(19) United States
(12) Patent Application Publication
(10) Pub. No.: US 2017/0012080 A1
(43) Pub. Date: Jan. 12, 2017

(54) METHOD OF FABRICATING SEMICONDUCTOR DEVICE

(71) Applicant: Powerchip Technology Corporation, Hsinchu (TW)

(72) Inventors: Shih-Ping Lee, Hsinchu City (TW); Yu-An Chen, Hsinchu City (TW); Hsiu-Wen Huang, Yunlin County (TW); Chuan-Hua Chang, New Taipei City (TW)

(21) Appl. No.: 14/855,395

(22) Filed: Sep. 16, 2015

(30) Foreign Application Priority Data
Jul. 8, 2015 (TW) 104122109

(51) Int. Cl. H01L 27/146; H01L 31/20

(52) U.S. Cl. CPC H01L 27/14687; H01L 31/208; H01L 27/14689

(57) ABSTRACT

A method of fabricating a semiconductor device includes the following steps. A substrate including an isolation region and a device region is provided. An overall amorphization process is performed on the substrate to form an amorphous region. Here, a minimum depth of the amorphous region is greater than a maximum depth of at least one of the isolation region and the device region, and the amorphous region covers at least one of the isolation region and the device region. A thermal treatment is performed on the amorphous region.

### CROSS-REFERENCE TO RELATED APPLICATION

This application claims the priority benefit of Taiwan application serial no. 104122109, filed on Jul. 8, 2015. The entirety of the above-mentioned patent application is hereby incorporated by reference herein and made a part of this specification.

### FIELD OF INVENTION

The invention relates to a method of fabricating a semiconductor device. More particularly, the invention relates to a method of fabricating a semiconductor device for repairing lattice defects.

### DESCRIPTION OF RELATED ART

Generally, as to fabrication of semiconductor devices, manufacturing defects often arise in the substrates, such as damages to sidewalls of shallow trench isolation (STI) structures, lattice defects including stacking fault or lattice dislocation caused by ion implantation, and so on, which often leads to current leakage of the semiconductor devices.

For instance, if the lattice defects including stacking fault or lattice dislocation exist in a complementary metal oxide semiconductor (CMOS) image sensor (CIS), the issue of dark current occurs, such that more read-out noises are generated, and that the image quality may be deteriorated. As such, performance of the CIS device may be lessened.

### SUMMARY

The invention is directed to a method of fabricating a semiconductor device for effectively rectifying lattice defects.

In an embodiment of the invention, a method of fabricating a semiconductor device includes the following steps. A substrate including an isolation region and a device region is provided. An overall amorphization process is performed on the substrate to form an amorphous region. Here, a minimum depth of the amorphous region is greater than a maximum depth of at least one of the isolation region and the device region, and the amorphous region covers at least one of the isolation region and the device region. A thermal treatment is performed on the amorphous region.

According to an embodiment of the invention, in the method of fabricating the semiconductor device, the overall amorphization process includes a pre-amorphization implant (PAI) process.

According to an embodiment of the invention, in the method of fabricating the semiconductor device, implant materials employed in the PAI process are germanium, silicon, argon, carbon, antimony, indium, fluorine, a combination thereof, or a molecular cluster thereof, for instance.

According to an embodiment of the invention, in the method of fabricating the semiconductor device, the PAI process is a cold-implant process, for instance.

According to an embodiment of the invention, in the method of fabricating the semiconductor device, the minimum depth of the amorphous region is from 0.1 micrometer to 10 micrometers, for instance.

According to an embodiment of the invention, in the method of fabricating the semiconductor device, the thermal treatment is an independent thermal treatment or a thermal treatment accompanying a subsequent manufacturing process, for instance.

According to an embodiment of the invention, in the method of fabricating the semiconductor device, the subsequent manufacturing process is a thermal oxidation process, a thermal deposition process, or a thermal annealing process, for instance.

According to an embodiment of the invention, in the method of fabricating the semiconductor device, a temperature at which the thermal treatment is performed is at least higher than 500° C., for instance.

According to an embodiment of the invention, in the method of fabricating the semiconductor device, a time frame during which the thermal treatment is performed is from 0.0001 second to 10 hours, for instance.

According to an embodiment of the invention, the method of fabricating the semiconductor device further includes forming an isolation structure in the isolation region.

According to an embodiment of the invention, in the method of fabricating the semiconductor device, the overall amorphization process is performed before or after the isolation structure is formed, and the isolation structure is, for instance, a shallow trench isolation (STI) structure or a deep trench isolation (DTI) structure.

According to an embodiment of the invention, in the method of fabricating the semiconductor device, the overall amorphization process is performed before or after the isolation structure is formed, and the isolation structure is, for instance, a junction isolation structure.

According to an embodiment of the invention, the method of fabricating the semiconductor device further includes forming a semiconductor device in the device region.

According to an embodiment of the invention, in the method of fabricating the semiconductor device, the semiconductor device is formed before or after the overall amorphization process is performed.

According to an embodiment of the invention, in the method of fabricating the semiconductor device, the semiconductor device is a photodiode, for instance.

According to an embodiment of the invention, in the method of fabricating the semiconductor device, the photodiode includes a first conductive type doped region and a second conductive type doped region adjacent to the first conductive type doped region.

According to an embodiment of the invention, in the method of fabricating the semiconductor device, a method for forming the photodiode is ion implantation, for instance.

According to an embodiment of the invention, the method of fabricating the semiconductor device further includes forming a transfer gate structure on the substrate at a side of the photodiode.

According to an embodiment of the invention, the method of fabricating the semiconductor device further includes removing end of range (EOR) defect regions in the amorphization region after performing the thermal treatment, and the EOR defect regions are located at an end of the amorphization region.

According to an embodiment of the invention, in the method of fabricating the semiconductor device, a method of removing the EOR defect regions is, for instance, a chemical mechanical polishing method, a wet dipping etching method, or a dry etching method.

In view of the above, according to the method of fabricating the semiconductor device provided herein, the amorphous region is formed in the substrate through performing the overall amorphization process, and the minimum depth of the amorphous region is greater than the maximum depth of at least one of the isolation region and the device region. Through performing the thermal treatment on the amorphous region, the amorphous region in the substrate is re-crystallized to form a solid phase epitaxial growth region, so as to rectify the lattice defects in the substrate and further reduce current leakage in the semiconductor device.

Several exemplary embodiments accompanied with figures are described in detail below to further describe the invention in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1A to FIG. 1F are cross-sectional views illustrating a method of manufacturing a semiconductor device according to an embodiment of the invention.

FIG. 2 is a cross-sectional view illustrating a structure of a semiconductor device according to another embodiment of the invention.

### DETAILED DESCRIPTION OF DISCLOSED EMBODIMENTS

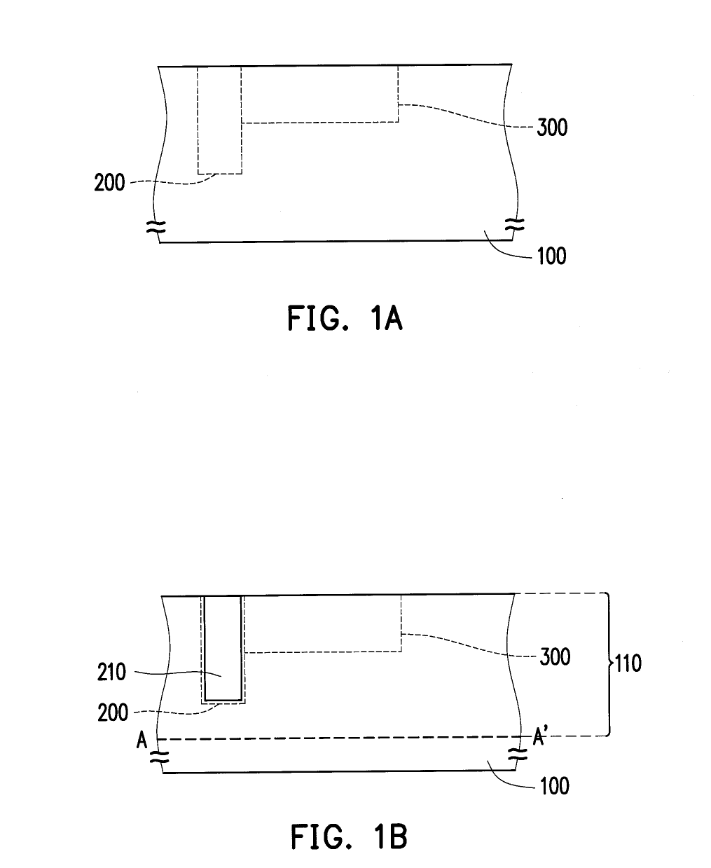

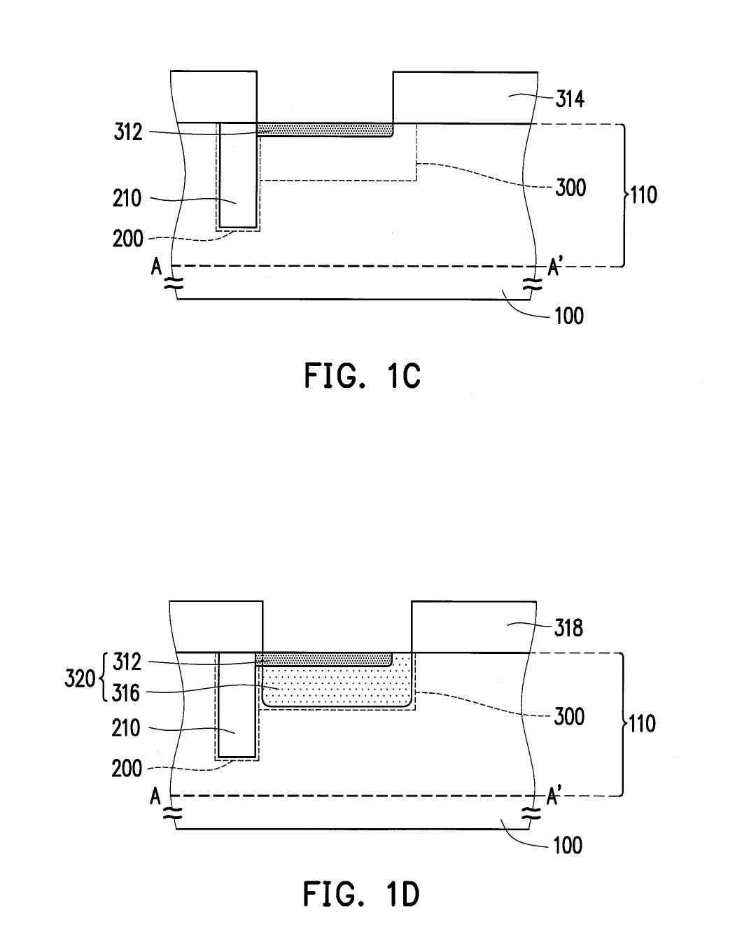

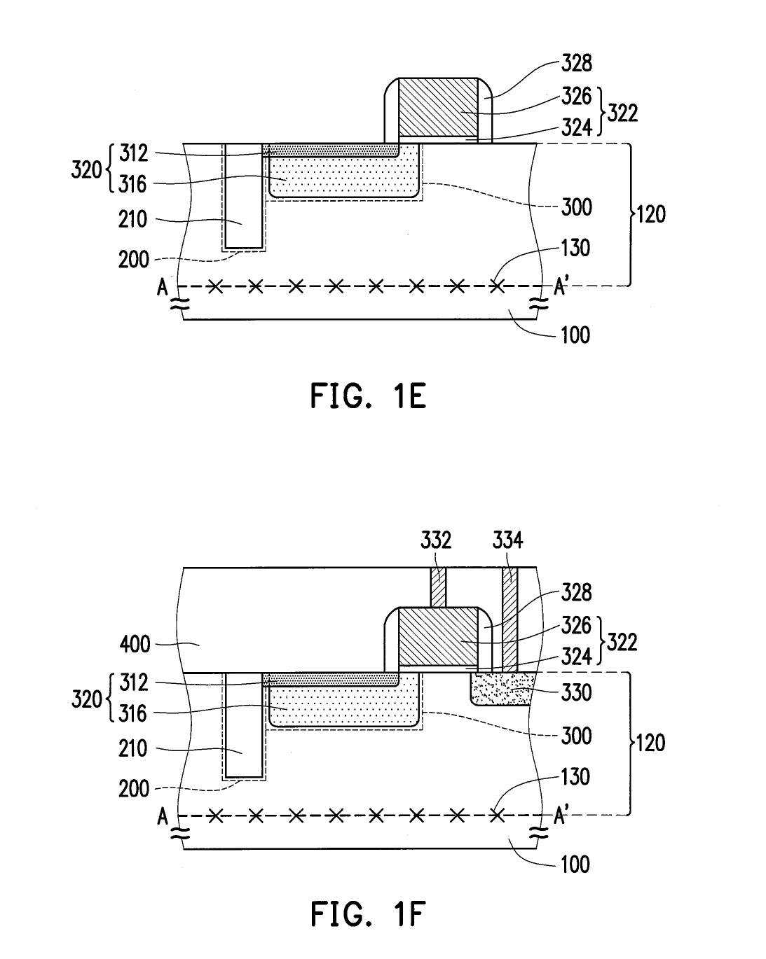

FIG. 1A to FIG. 1F are cross-sectional views illustrating a method of manufacturing a semiconductor device according to an embodiment of the invention.

With reference to FIG. 1A, a substrate 100 is provided. The substrate 100 is, for example, a silicon substrate. P-type dopants or an n-type dopants may be implanted into the substrate 100 to form a p-type substrate or an n-type substrate. According to the present embodiment, the substrate 100 is, for instance, the p-type substrate.

The substrate 100 includes an isolation region 200 and a device region 300. An isolation structure is to be formed in the isolation region 200, and the semiconductor device is to be formed in the device region 300.

With reference to FIG. 1B, an isolation structure 210 can be formed in the isolation region 200. The isolation structure 210 is a shallow trench isolation (STI) structure, a deep trench isolation (DTI) structure, or a junction isolation structure, for instance. In the present embodiment, the isolation structure 210 in the isolation region 200 is the STI structure, for instance. If the isolation structure 210 is the STI structure, a method of forming the isolation structure 210 includes firstly forming an opening in the substrate 100 and filling the opening with a dielectric material, for instance. The STI structure is made of silica, silicon nitride, silicon carbide, and any other isolation material, for instance. Nevertheless, the invention should not be construed as limited to the embodiments set forth herein. The isolation structure may also be an STI structure or a DTI structure formed by applying other methods. For instance, in an embodiment of the invention, if the isolation structure 210 is the STI structure, the isolation structure 210 is formed through separation by implantation of oxygen (SIMOX); for instance, oxygen ions may be implanted in the substrate 100, and oxide is then formed at a high temperature. In another embodiment of the invention, the isolation structure 210 may also be a junction isolation structure. If the isolation structure 210 is the junction isolation structure, the isolation structure 210 is formed by forming a patterned photoresist layer (not shown) on the substrate 100 and implanting dopants into the substrate 100 exposed by the patterned photoresist layer through ion implantation, so as to form the junction structure in the substrate 100.

An overall amorphization process is performed on the substrate 100 to form an amorphous region 110. The amorphous region 110 is the region above the line A-A′ in the substrate 100, for instance. A minimum depth of the amorphous region 110 is greater than a maximum depth of at least one of the isolation region 200 and the device region 300, and the amorphous region 110 covers at least one of the isolation region 200 and the device region 300. In the present embodiment, the minimum depth of the amorphous region 110 is greater than the maximum depths of the isolation region 200 and the device region 300, for instance, and the amorphous region 110 covers both the isolation region 200 and the device region 300, for instance; however, the invention is not limited thereto. The overall amorphization process is, for instance, a pre-amorphization implant (PAI) process, for instance. Implant materials employed in the PAI process are, for instance, germanium, silicon, argon, carbon, antimony, indium, fluorine, a combination thereof, or a molecular cluster thereof. The PAI process is a cold-implant process, for instance. If the PAI process adopts the cold-implant process, density of defects in end of range (EOR) defect regions can be reduced. The minimum depth of the amorphous region is from 0.1 micrometer to 10 micrometers, for instance; however, the invention is not limited thereto.

In the present embodiment, if the isolation structure 210 is the STI structure or the DTI structure, the overall amorphization process may be performed before or after the isolation structure 210 is formed. In another embodiment, if the isolation structure 210 is the junction isolation structure, the overall amorphization process may also be performed before or after the isolation structure 210 is formed. If the overall amorphization process is performed before the junction isolation structure 210 is formed, the junction isolation structure 210 can be protected from being deformed during the overall amorphization process.

With reference to FIG. 1C, after the overall amorphization process is performed, a first conductive type doped region 312 may be formed in the device region 300 of the substrate 100. A method of forming the first conductive type doped region 312 in the substrate 100 includes the following steps, for instance. A patterned photoresist layer 314 is formed on the substrate 100. A method of forming the patterned photoresist layer 314 is, for instance, photolithography. First conductive types dopant may be implanted through ion implantation into the substrate 100 exposed by the patterned photoresist layer 314, so as to form the first conductive type doped region 312. In the present embodiment, the first conductive type dopants are the p-type dopants, e.g., boron; however, the invention is not limited thereto. A dosage of the first conductive type dopants ranges from 1E11/cm² to 1E17/cm², for instance.

With reference to FIG. 1D, the patterned photoresist layer 314 is removed. A method of removing the patterned photoresist layer 314 includes, for instance, performing a wet stripping process or a dry stripping process.

Thereafter, a second conductive type doped region 316 may be formed in the device region 300 of the substrate 100, and the second conductive type doped region 316 is adjacent to the first conductive type doped region 312. In the present embodiment, the second conductive type doped region 316 is arranged below the first conductive type doped region 312, for instance. Besides, the second conductive type doped region 316 may adjoin a channel region below a subsequently formed transfer gate structure. A method of forming the second conductive type doped region 316 in the substrate 100 includes the following steps, for instance. A patterned photoresist layer 318 is formed on the substrate 100. Second conductive type dopants may be implanted through ion implantation into the substrate 100 exposed by the patterned photoresist layer 318, so as to form the second conductive type doped region 316. In the present embodiment, the second conductive type dopants are the n-type dopants, e.g., phosphorous (P) or arsenic (As); however, the invention is not limited thereto. A dosage of the second conductive type dopants ranges from 1E11/cm² to 1E17/cm², for instance.

In the present embodiment, the substrate 100 is the p-type substrate; therefore, the first conductive type doped region 312 is the p-type doped region, for instance, and the second conductive type doped region 316 is the n-type doped region, for instance. In another embodiment of the invention, if the substrate 100 is the n-type substrate, the first conductive type doped region 312 may be the n-type doped region, for instance, and the second conductive type doped region 316 may be the p-type doped region, for instance.

At this time, a photodiode 320 (the semiconductor device) can be formed in the device region 300 through the first and second conductive type doped regions 312 and 316, and a P/N junction is formed at the junction between the first conductive type doped region 312 and the second conductive type doped region 316. The P/N junction of the photodiode 320 further includes the P/N junction between the second conductive type doped region 316 and the doped region surrounding the second conductive type doped region 316. Here, the surrounding doped region is, for instance, a p-type base material, and the polarity of the surrounding doped region is different from that of the second conductive type doped region 316. It should be mentioned that the photodiode 320 (the semiconductor device) is formed after the overall amorphization process is performed. Nevertheless, the invention should not be construed as limited to the embodiments set forth herein. It should be mentioned that the photodiode 320 (the semiconductor device) may also be formed before the overall amorphization process is performed.

With reference to FIG. 1E, the patterned photoresist layer 318 is removed. A method of removing the patterned photoresist layer 318 includes, for instance, performing a wet stripping process or a dry stripping process.

A thermal treatment is performed on the amorphous region 110, so as to re-crystallize the amorphous region 110 and form a solid phase epitaxial growth region 120; thereby, the lattice defects in the substrate 100 can be rectified. For instance, the lattice defects arising in the substrate 100 during the aforesaid semiconductor manufacturing process, e.g., forming the isolation structure 210 or the photodiode 320 (the semiconductor device), may be rectified. The thermal treatment includes an independent thermal treatment or a thermal treatment accompanying a subsequent manufacturing process, for instance. That is, if the temperature at which the subsequent manufacturing process is performed is higher than the temperature at which the amorphous region 110 is re-crystallized, it is not necessary to independently perform any additional thermal treatment. The independent thermal treatment is, for example, an annealing process. The subsequent manufacturing process is, for instance, a thermal oxidation process, a thermal deposition process, or a thermal annealing process. The temperature at which the thermal treatment is performed is higher than 500° C., for instance; a time frame during which the thermal treatment is performed is from 0.0001 second to 10 hours, for instance.

After the thermal treatment is performed, lattice defects may still exist at the end of the amorphous region 110 (i.e., the line A-A′), thus resulting in the formation of EOR defect regions 130 (located around the line A-A′ on the substrate 100). Since the distance from the EOR defect regions 130 to the isolation region 200 or to the device region 300 is rather far, and thus the EOR defect regions 130 do not pose any significant impact on the photodiode 320 (the semiconductor device) in the device region 300. Besides, the thermal treatment allows the amorphous region 110 to be re-crystallized to form the solid phase epitaxial growth region 120 of which the lattices are re-arranged, such that the issue of lattice defects can be resolved. That is, the lattice defects in the isolation region 200 and the device region 300 can be rectified; as such, dark current caused by the lattice defects can be prevented from being generated in the CIS, the signal-to-noise (S/N) ratio can be improved, and the performance of the CIS can be raised.

A transfer gate structure 322 can be formed on the substrate 100 at a side of the photodiode 320. The transfer gate structure 322 includes a gate dielectric layer 324 and a transfer gate 326 arranged on the gate dielectric layer 324. A method for fabricating the gate dielectric layer 324 and the transfer gate 326 includes, for instance, forming a gate dielectric material layer (not shown) and a transfer gate material layer (not shown) sequentially on the substrate 100 and performing a patterning process on the transfer gate material layer and the gate dielectric material layer. The gate dielectric material layer is made of silicon oxide, for instance. The gate dielectric material layer is formed by performing a thermal oxidation process or a chemical vapor deposition (CVD) process, for instance. A material of the transfer gate material layer is, for instance, doped polysilicon. The transfer gate material layer is formed by performing a CVD process, for instance. In other embodiments, it is likely to selectively form a silicide layer on the transfer gate 326.

Spacers 328 can be formed at two sides of the transfer gate structure 322. The spacers 328 are made of silicon nitride, for example. In a method of forming the spacers 328, for example, a spacer material layer (not illustrated) covering the transfer gate structure 322 is formed on the substrate 100, and an etching back process is performed on the spacer material layer by performing a dry etching process, so as to form the spacers 328.

With reference to FIG. 1F, a floating diffusion region 330 may be formed in the substrate 100 at a side of the transfer gate structure 322 away from the photodiode 320. The floating diffusion region 330 is formed by performing an ion implantation process, for instance. The conductive type of the floating diffusion region 330 is the same as that of the second conductive type doped region 316, for instance. In the present embodiment, the floating diffusion region 330 is, for example, an n-type doped region; however, the invention is not limited thereto.

A dielectric layer 400 covering the transfer gate structure 322 and the spacers 328 may be formed on the substrate 100. The dielectric layer 400 is made of silicon oxide, for example. A method for forming the dielectric layer 400 is, for example, CVD.

A plug 332 connected to the transfer gate 326 and a plug 334 connected to the floating diffusion region 330 may be respectively formed in the dielectric layer 400, and the plugs 332 and 334 may be electrically connected to subsequently formed conductive wires or other devices. The plugs 332 and 334 are made of metal, such as tungsten, copper, and so forth. Besides, the plugs 332 and 334 are formed by performing a damascene process, for instance.

In the present embodiment, the CIS refers to a front side illuminated (FSI) image sensor, for instance. That is, the light source emits light to the front side of the substrate 100, and it is not necessary to perform a bottom thinning process on the rear side of the substrate 100. That is, the EOR defect regions 130 on the amorphous region 110 still exist. As discussed above, the distance from the EOR defect regions 130 to the isolation region 200 or to the device region 300 is rather far, and thus the EOR defect regions 130 do not pose any significant impact on the semiconductor device in the device region 300. Besides, the EOR defect regions 130 are capable of absorbing metallic impurities or contaminants.

In the present embodiment, the semiconductor device refers to the photodiode in the CIS, for instance, which should however not be construed as a limitation to the invention. After considering the way to rectify the lattice defects provided above, people having ordinary skill in the pertinent art should be able to apply the aforesaid method of fabricating the semiconductor device to other semiconductor devices having the to-be-rectified lattice defects.

In light of the foregoing, the amorphous region 110 is formed in the substrate 100 through performing the overall amorphization process, and the minimum depth of the amorphous region 110 is greater than the maximum depth of at least one of the isolation region 200 and the device region 300. Through performing the thermal treatment on the amorphous region 110, the amorphous region 110 in the substrate 100 is re-crystallized to form the solid phase epitaxial growth region 120, so as to rectify the lattice defects in the substrate 100 and further reduce current leakage in the semiconductor device.

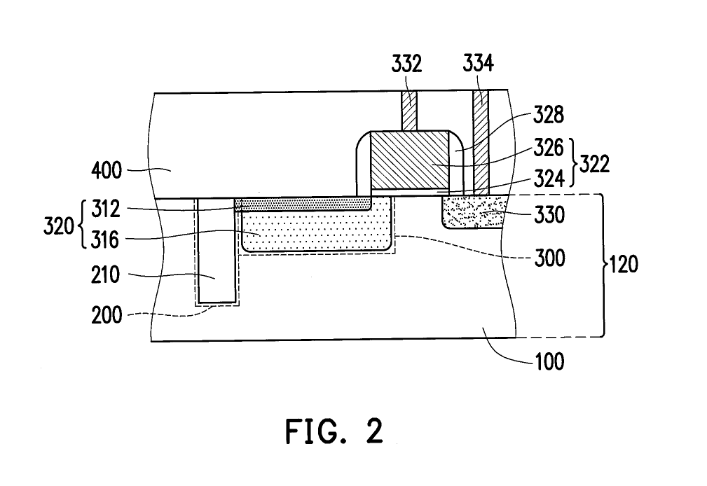

FIG. 2 is a cross-sectional view illustrating a structure of a semiconductor device according to another embodiment of the invention.

With reference to FIG. 1F and FIG. 2, the difference between the embodiment shown in FIG. 1F and the embodiment shown in FIG. 2 lies in that the CIS depicted in FIG. 2 is a backside illuminated (BSI) image sensor. That is, the light source emits light to the rear side of the substrate 100. Hence, the method of fabricating the semiconductor device of FIG. 2 further includes performing a bottom thinning process on the rear side of the substrate 100, so as to shorten the distance from the rear side of the substrate 100 to the photodiode 320. The EOR defect regions 130 can be simultaneously removed by performing the bottom thinning process. The EOR defect regions 130 are removed by applying a chemical mechanical polishing method, a wet dipping etching method, a dry etching method, and so on, for instance. The arrangements, materials, effects, and manufacturing methods of other components provided in FIG. 2 are similar to those provided in FIG. 1F, and thus no further description is provided hereinafter.

To sum up, the method of fabricating the semiconductor device provided in the embodiments above has at least the following advantages. The amorphous region is formed in the substrate through performing the overall amorphization process, and the minimum depth of the amorphous region is greater than the maximum depth of at least one of the isolation region and the device region. Through performing the thermal treatment on the amorphous region, the amorphous region in the substrate is re-crystallized to form a solid phase epitaxial growth region, so as to rectify the lattice defects in the substrate and further reduce current leakage in the semiconductor device.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

1. A method of fabricating a semiconductor device, comprising:
providing a substrate comprising an isolation region and a device region;
performing an overall amorphization process on the substrate to form an amorphous region, wherein a minimum depth of the amorphous region is greater than a maximum depth of at least one of the isolation region and the device region, and the amorphous region covers the isolation region and the device region; and
performing a thermal treatment on the amorphous region.

2. The method of claim 1, wherein the overall amorphization process comprises a pre-amorphization implant process.

3. The method of claim 2, wherein implant materials employed in the pre-amorphization implant process comprise germanium, silicon, argon, carbon, antimony, indium, fluorine, a combination thereof, or a molecular cluster thereof.

4. The method of claim 2, wherein the pre-amorphization implant process comprises a cold-implant process.

5. The method of claim 1, wherein the minimum depth of the amorphous region is from 0.1 micrometer to 10 micrometers.

6. The method of claim 1, wherein the thermal treatment comprises an independent thermal treatment or a thermal treatment accompanying a subsequent manufacturing process.

7. The method of claim 6, wherein the subsequent manufacturing process comprises a thermal oxidation process, a thermal deposition process, or a thermal annealing process.

8. The method of claim 1, wherein a temperature at which the thermal treatment is performed is at least higher than 500° C.

9. The method of claim 1, wherein a time frame during which the thermal treatment is performed is from 0.0001 second to 10 hours.

10. The method of claim 1, further comprising forming an isolation structure in the isolation region.

11. The method of claim 10, wherein the overall amorphization process is performed before or after the isolation structure is formed, and the isolation structure comprises a shallow trench isolation structure or a deep trench isolation structure.

12. The method of claim 10, wherein the overall amorphization process is performed before or after the isolation structure is formed, and the isolation structure comprises a junction isolation structure.

13. The method of claim 1, further comprising forming a semiconductor device in the device region.

14. The method of claim 13, wherein the semiconductor device is formed before or after the overall amorphization process is performed.

15. The method of claim 13, wherein the semiconductor device comprises a photodiode.

16. The method of claim 15, wherein the photodiode comprises a first conductive type doped region and a second conductive type doped region adjacent to the first conductive type doped region.

17. The method of claim 15, wherein a method for forming the photodiode comprises ion implantation.

18. The method of claim 15, further comprising forming a transfer gate structure on the substrate at a side of the photodiode.

19. The method of claim 1, further comprising removing end of range defect regions in the amorphization region after performing the thermal treatment, wherein the end of range defect regions are located at an end of the amorphization region.

20. The method of claim 19, wherein a method of removing the end of range defect regions comprises a chemical mechanical polishing method, a wet dipping etching method, or a dry etching method.
